(19) United States
(12) Patent Application Publication
(10) Pub. No.: US 2015/0232980 A1
(43) Pub. Date: Aug. 20, 2015

(54) Cu-Ga Alloy Sputtering Target, and Method for Producing Same

(71) Applicant: JX Nippon Mining & Metals Corporation, Tokyo (JP)

(72) Inventor: Tomoya Tamura, Ibaraki (JP)

(21) Appl. No.: 14/421,036

(22) PCT Filed: Oct. 28, 2013
(86) PCT No.: PCT/JP2013/079062

§ 371 Date: Feb. 11, 2015

(30) Foreign Application Priority Data
Nov. 13, 2012 (JP) 2012-249151

(51) Int. Cl. C23C 14/34; H01J 37/34; C22C 28/00; B22D 11/124; B22D 11/041; B22D 11/045; C23C 14/14; B22D 11/126

(52) U.S. Cl. CPC C23C 14/3414; C23C 14/14; H01J 37/3429; B22D 11/126; B22D 11/124; B22D 11/041; B22D 11/045; C22C 28/00; H01J 2237/3322

(57) ABSTRACT

A melted and cast Cu—Ga alloy sputtering target containing 22 at % or more and 29 at % or less of Ga, and remainder being Cu and unavoidable impurities, wherein the Cu—Ga alloy sputtering target has an eutectoid structure configured from a mixed phase of a ζ phase, which is an intermetallic compound layer of Cu and Ga, and a γ phase, and satisfies a relational expression of D≦7×C−150 when a diameter of the γ phase is D μm and a Ga concentration is C at %. A sputtering target having a cast structure is advantageous in that gas components such as oxygen can be reduced in comparison to a sintered compact target. Thus, it is possible to reduce oxygen and obtain a target with a favorable cast structure, in which the segregated phase is dispersed, by continuously solidifying the sputtering target having the foregoing cast structure under a solidifying condition of a constant cooling rate.

### BACKGROUND

The present invention relates to a Cu—Ga alloy sputtering target to be used upon forming a Cu—In—Ga—Se (hereinafter indicated as “CIGS”) quaternary alloy thin film, which is a light-absorbing layer of a thin film solar cell layer, and to a method of producing such a target.

In recent years, the mass production of CIGS-based solar cells which are highly efficient for use as thin film solar cells is progressing, and as a method of producing the light-absorbing layer, the vapor-deposition technique and the selenization method are known. While the solar cells produced via the vapor-deposition technique are advantageous of having high conversion efficiency, they also have drawbacks; namely, low deposition rate, high cost, and low productivity, and the selenization method is more suitable for industrial mass production.

The process of the selenization method can be summarized as follows. Foremost, a molybdenum electrode layer is formed on a soda lime glass substrate, a Cu—Ga layer and an In layer are sputter-deposited thereon, and a CIGS layer is thereafter formed based on high temperature treatment in selenium hydride gas. The Cu—Ga target is used during the sputter deposition of the Cu—Ga layer during the process of forming the CIGS layer based on the foregoing selenization method.

While the conversion efficiency of the CIGS-based solar cells is affected by various manufacturing conditions and characteristics of the constituent materials, the characteristics of the CIGS film also considerably affect the conversion efficiency of the CIGS-based solar cells.

As methods of producing the Cu—Ga target, there are the melting method and the powder method. Generally, while it is said that the impurity contamination of the Cu—Ga target produced via the melting method is relatively low, the Cu—Ga target produced via the melting method also has numerous drawbacks. For example, since the cooling rate cannot be increased, compositional segregation is considerable, and the composition of the film prepared via the sputtering method will gradually change.

Moreover, ingot piping tends to occur during the final stage of cooling the molten metal, and, since the characteristics of the portion around the ingot piping are inferior and such portion cannot be used in the process of processing the target into a predetermined shape, the production yield is inferior.

While the prior art document (Patent Document 1) pertaining to the Cu—Ga target based on the melting method describes that compositional segregation could not be observed, analysis results and the like are not indicated in any way. Moreover, the Examples of Patent Document 1 only indicate the results of 30 wt % as the Ga concentration, but do not provide any other description regarding characteristics such as the structure or segregation in a lower Ga concentration region.

Meanwhile, a target produced via the powder method generally had problems such as the sintered density being low and the impurity concentration being high. While Patent Document 2 relating to the Cu—Ga target describes a sintered compact target, the description is an explanation of conventional technology related to brittleness to the effect that cracks and fractures tend to occur upon cutting a target, and Patent Document 2 produces two types of powders and mixes and sinters these powders in order to resolve the foregoing problem. Among the two types of powders described above, one is powder with a high Ga content and the other is powder with a low Ga content, and Patent Document 2 achieves a two-phase coexisting structure that is encircled by the grain boundary phase.

This process is complicated since two types of powders need to be produced, and, since metal powders increase the oxygen concentration, improvement in the relative density cannot be expected.

A target with a low density and a high oxygen concentration is obviously subject to abnormal discharge and generation of particles, and, if there is foreign matter such as particles on the sputtered film surface, it will also have an adverse effect on the subsequent CIGS film characteristics, and it is highly likely that it will ultimately lead to the considerable deterioration in the conversion efficiency of the CIGS solar cells.

A major problem in the Cu—Ga sputtering target prepared based on the powder method is that the process is complicated, and the quality of the prepared sintered compact is not necessarily favorable, and there is also a significant disadvantage in that the production cost will increase. From this perspective, the melting and casting method is desirable, but as described above, there are problems in the production process, and the quality of the target itself could not be improved.

As conventional technology, there is, for instance, Patent Document 3. Here, described is technology of processing a target by subjecting high purity copper and copper alloy doped with trace amounts of titanium in an amount of 0.04 to 0.15 wt % or zinc in an amount of 0.014 to 0.15 wt % to continuous casting.

Since the amount of additive elements of this kind of alloy is a trace amount, this method cannot be applied to the production of alloys containing a large amount of additive elements.

Patent Document 4 discloses a technique of continuously casting high purity copper in a rod shape in a manner that is free of casting defects, and rolling and processing the obtained product and into a sputtering target. This technique is limited to cases where the raw material is a pure metal, and cannot be applied to the production of alloys containing a large amount of additive elements.

Patent Document 5 describes adding a material selected among 24 elements such as Ag and Au to aluminum in an amount of 0.1 to 3.0 wt % and performing continuous casting thereto in order to produce a single-crystallized sputtering target. Since the amount of additive elements of this kind of alloy is also a trace amount, this method cannot be applied to the production of alloys containing a large amount of additive elements.

While foregoing Patent Documents 3 to 5 illustrate examples of producing a target based on the continuous casting method, in all examples the additive elements are added to a pure metal or an alloy doped with a trace amount of additive elements, and it cannot be said that Patent Documents 3 to 5 offer any disclosure capable of resolving the problems existing in the production of a Cu—Ga alloy target with a large amount of additive elements and in which the segregation of intermetallic compounds tends to occur.

### PRIOR ART DOCUMENTS

### Patent Documents

Patent Document 1: JP-A-2000-73163
Patent Document 2: JP-A-2008-138232
Patent Document 3: JP-A-H5-311424
Patent Document 4: JP-A-2005-330591
Patent Document 5: JP-A-H7-300667
Patent Document 6: JP-A-2012-17481

### SUMMARY OF THE INVENTION

### Problems to be Solved by the Invention

With a Cu—Ga alloy containing Ga in an amount of 22% or more, the segregation of an intermetallic compound tends to occur, and it is difficult to finely and uniformly disperse the segregation with the normal melting method. Meanwhile, a sputtering target having a cast structure is advantageous in that gas components such as oxygen can be reduced in comparison to a sintered compact target. Thus, an object of the present invention is to reduce oxygen and obtain a target with a favorable cast structure, in which the segregated phase is dispersed, by continuously solidifying the sputtering target having the foregoing cast structure under a solidifying condition of a constant cooling rate.

### Means for Solving the Problems

In order to achieve the foregoing object, as a result of intense study, the present inventors discovered that it is possible to reduce oxygen and obtain a Cu—Ga alloy sputtering target with a favorable cast structure, in which the γ phase is finely and uniformly dispersed in the ζ phase of an intermetallic compound as the parent phase, by adjusting the component composition and performing continuous casting, and thereby completed this invention.

Based on the foregoing discovery, the present invention provides the following invention.

1) A melted and cast Cu—Ga alloy sputtering target containing 22 at % or more and 29 at % or less of Ga, and remainder being Cu and unavoidable impurities, wherein the Cu—Ga alloy sputtering target has an eutectoid structure (excluding a structure containing a lamellar structure) configured from a mixed phase of a ζ phase, which is an intermetallic compound layer of Cu and Ga, and a γ phase, and satisfies a relational expression of D≦7×C−150 when a diameter of the γ phase is D μm and a Ga concentration is C at %.

2) The Cu—Ga alloy sputtering target according to 1) above, wherein an oxygen content is 100 wt.ppm or less.

3) The Cu—Ga alloy sputtering target according to 1) or 2) above, wherein content of Fe, Ni, Ag and P as impurities is each 10 wtppm or less.

Moreover, the present invention provides the following invention.

4) A method of producing a Cu—Ga alloy sputtering target including the steps of melting a target raw material in a graphite crucible, pouring resulting molten metal in a mold comprising a water-cooled probe to continuously produce a casting formed from a Cu—Ga alloy, and additionally machining the obtained casting to produce the Cu—Ga alloy target, wherein a solidification rate of the casting reaching 300° C. from a melting point is controlled to 200 to 1000° C./min.

5) The method of producing a Cu—Ga alloy sputtering target according to 4) above, wherein a drawing rate is set to 30 mm/min to 150 mm/min.

6) The method of producing a Cu—Ga alloy sputtering target according to 4) or 5) above, wherein a horizontal or a vertical continuous casting method is adopted.

7) The method of producing a Cu—Ga alloy sputtering target according to any one of 4) to 6) above, wherein an amount and a concentration of a γ phase and a ζ phase formed during casting is adjusted by controlling the solidification rate of the casting reaching 300° C. from the melting point is controlled to 200 to 1000° C./min.

### Effect of the Invention

According to the present invention, there is a considerable advantage in that gas components such as oxygen can be reduced in comparison to a sintered compact target, and, by continuously solidifying the sputtering target having the foregoing cast structure under a solidifying condition of a constant cooling rate, the present invention yields the effect of being able to reduce oxygen and obtain a target with a favorable cast structure, in which the γ phase is finely and uniformly dispersed in the ζ phase of an intermetallic compound as the parent phase.

As a result of sputtering a Cu—Ga alloy target with a low oxygen content and having a cast structure in which the segregation is dispersed, the present invention yields the effect of being able to obtain a homogeneous Cu—Ga-based alloy film with low generation of particles, and additionally yields the effect of being able to considerably reduce the production cost of the Cu—Ga alloy target.

Since the light-absorbing layer and CIGS-based solar cells can be produced from the foregoing sputtered film, the present invention yields superior effects of being able to inhibit the deterioration in the conversion efficiency of the CIGS solar cells, as well as produce low-cost GIGS-based solar cells.

### BRIEF DESCRIPTION OF THE DRAWINGS

FIG. 1 is a scanning electron microscope (SEM) photo of the surface after etching the polished surface of the target of Example 3 with a diluted nitric acid solution.

FIG. 2 is a scanning electron microscope (SEM) photo of the surface after etching the polished surface of the target of Example 5 with a diluted nitric acid solution.

FIG. 3 is a scanning electron microscope (SEM) photo of the surface after etching the polished surface of the target of Comparative Example 2 with a diluted nitric acid solution.

FIG. 4 is a scanning electron microscope (SEM) photo of the surface after etching the polished surface of the target of Comparative Example 3 with a diluted nitric acid solution.

FIG. 5 is a scanning electron microscope (SEM) photo of the surface after etching the polished surface of the target of Comparative Example 5 with a diluted nitric acid solution.

FIG. 6 is a scanning electron microscope (SEM) photo of the surface after etching the polished surface of the target of Comparative Example 6 with a diluted nitric acid solution.

FIG. 7 is a diagram showing the results of the FE-EPMA surface analysis of the polished surface of the target of Example 4 (upper left diagram) and Example 6 (lower left diagram), and of Comparative Example 3 (upper right diagram) and Comparative Example 6 (lower right diagram).

FIG. 8 is a diagram showing the results of analyzing, via X-ray diffraction, the target surface of Example 3 (upper diagram) and Example 6 (lower diagram).

### DETAILED DESCRIPTION OF EMBODIMENT

The Cu—Ga alloy sputtering target of the present invention is a melted and cast Cu—Ga alloy sputtering target containing 22 at % or more and 29 at % or less of Ga and remainder being Cu and unavoidable impurities.

Generally speaking, a sintered article ideally has a relative density of 95% or more. This is because, if the relative density is low, generation of particles onto the film and surface unevenness advances rapidly due to the splashes or abnormal discharge that occur around the holes during the emergence of inner holes during sputtering, and abnormal discharge and the like tend to occur with the surface protrusions (nodules) as the starting point. A casting is able to achieve a relative density of substantially 100%, and is consequently effective for inhibiting the generation of particles during sputtering. This is a major advantage of a casting.

The Ga content is something that is required from demands of forming a Cu—Ga alloy sputtered film that is needed upon producing CIGS-based solar cells, and the Cu—Ga alloy sputtering target of the present invention is a melted and cast Cu—Ga alloy sputtering target containing 22 at % or more and 29 at % or less of Ga, and remainder being Cu and unavoidable impurities.

When the Ga content is less than 22%, a dendrite structure configured from an α phase or from an α phase and a ζ phase is formed, and when the Ga content exceeds 29%, a structure configured from a γ phase, single phase is formed, and the intended structure cannot be obtained. Accordingly, the Ga content is set to be 22 at % or more and 29 at % or less.

In addition, the melted and cast Cu—Ga alloy sputtering target of the present invention has an eutectoid structure configured from a mixed phase of a ζ phase, which is an intermetallic compound layer of Cu and Ga, and a γ phase. However, a structure containing a lamellar structure (layered structure) is excluded from the eutectoid structure. A lamellar structure is a structure in which two phases (γ phase and ζ phase) alternatively exist in a thin plate shape or an oval shape in intervals of several microns as shown in Comparative Example 2 (FIG. 3) described later. When this kind of structure partially exists, due to the difference in the state compared with the peripheral structure, it is undesirable since defects such as an abnormal discharge occur during sputtering. In the present invention, a lamellar structure is specifically defined as a structure that satisfies a/b≦0.3 or less when the short side of the γ phase (portion that appears concave in FIG. 3) is a and the long side is b.

Moreover, the γ phase is finely and uniformly dispersed in the ζ phase of an intermetallic compound as the parent phase, and the size of the γ phase satisfies the formula of D≦7×C−150 when the diameter of the γ phase is D (μm) and the Ga concentration is C (at %).

After confirming that target structure is configured from a ζ phase and a γ phase based on the XRD diffraction method, since the Ga concentration was higher in the γ phase than the ζ phase, the portion where the Ga concentration is higher (darker portion) in the FE-EPMA can be recognized as the γ phase. The diameter of the γ phase can be calculated by extracting a plurality of (roughly 30) γ phases randomly from the SEM photo (magnification: 1000×), and taking the average of their sizes (diameters). Moreover, the γ phase may exist in the form of oval shapes in addition to spherical shapes, and in such a case, the average value of the short side and the long side may be used as the size (diameter) of the γ phase.

The structure of the melted and cast Cu—Ga alloy will differ depending on the structure that is obtained based on the solidifying conditions such as the cooling rate. For example, Patent Document 6 describes an eutectoid structure configured from a mixed phase of a β phase, which is a mother phase, and a γ phase. Nevertheless, this β phase is a phase that is unstable in a high-temperature range of approximately 600° C. or higher, and will not exist at room temperature unless it is cast via rapid cooling, a β phase will never be precipitated under the solidifying conditions of the present invention.

As described above, the finely and uniformly dispersed γ phase is extremely effective for forming a film. The γ phase is affected by the cooling rate, and a fine γ phase grows rapidly when the cooling rate is fast. The γ phase can also be referred to as a segregated phase, but in order to cause the γ phase to be finely and uniformly dispersed, the sputtering target is continuously solidified under a solidifying condition of a constant cooling rate. This is a major feature of the present invention. Upon observing the overall structure of the sputtering target, it can be seen that it is a uniform structure without any large segregation.

The method of producing a Cu—Ga alloy sputtering target including the steps of melting a target raw material in a graphite crucible, pouring the resulting molten metal in a mold comprising a water-cooled probe to continuously produce a casting formed from a Cu—Ga alloy, and additionally machining the obtained casting to produce the Cu—Ga alloy target, and the solidification rate of the casting reaching 300° C. from a melting point is preferably controlled to 200 to 1000° C./min. It is thereby possible to produce the foregoing target.

The foregoing casting can be produced into a plate shape using a mold, but it is also possible to produce a cylindrical casting by using a mold comprising a core cylinder. Note that, however, there is no particular limitation in the shape of the casting to be produced in the present invention.

In addition, as an efficient and effective measures of producing the Cu—Ga alloy sputtering target, the drawing rate is desirably set to be 30 mm/min to 150 mm/min; and such a continuous method of casting can be effectively performed using the continuous casting method.

By controlling the solidification rate of the casting reaching 300° C. from a melting point to be 200 to 1000° C./min as described above, the amount and concentration of the mixed phase of the ζ phase and the γ phase that is formed during casting can be easily adjusted.

The Cu—Ga alloy sputtering target of the present invention can cause the oxygen content to be 100 wtppm or less, and preferably 50 wtppm or less, and this can be achieved by adopting measures for preventing the mixture of air (for example, selection of sealing materials for the mold and fireproof materials, and introduction of argon gas or nitrogen gas at such sealed portion) during the degassing and casting processes of the Cu—Ga alloy molten metal.

As with the foregoing requirement, this is also a favorable requirement for improving the characteristics of CIGS-based solar cells. Moreover, it is thereby possible to suppress the generation of particles during sputtering, and yielded is an effect of being able to reduce the oxygen in the sputtered film, and suppressing the formation of oxides and suboxides caused by internal oxidation.

With the Cu—Ga alloy sputtering target of the present invention, the content of Fe, Ni, Ag and P as impurities can each be made 10 wtppm or less. Since these impurity elements (particularly Fe and Ni) deteriorate the characteristics of CIGS-based solar cells, being able to reduce such impurities to be 10 wtppm or less is extremely effective. These impurity elements are contained in the raw material or get mixed in during the respective production processes, but based on the continuous casting method, the content of these impurities can be kept low (zone melting method). Ag is an element that gets mixed in at an order of several ten wtppm particularly due to the raw material Cu, but by performing continuous casting, the Ag content can be made to be 10 wtppm or less.

Upon producing the Cu—Ga alloy sputtering target, the casting that was abstracted from the mold may be subject to machining and surface polishing to obtain a target. Conventional techniques may be used for the foregoing machining and surface polishing, and there are no particular limitations to the conditions thereof.

Upon producing the light-absorbing layer and CIGS-based solar cells from a Cu—Ga-based alloy film, deviation in the composition will considerably change the characteristics of the light-absorbing layer and the CIGS-based solar cells. However, when deposition is performed using the Cu—Ga alloy sputtering target of the present invention, no such deviation of composition can be observed. This is a major advantage of a casting in comparison to a sintered article.

### EXAMPLES

The Examples of the present invention are now explained. Note that the following Examples merely illustrate representative examples, and the present invention should not be limited to these Examples. In other words, the present invention covers all modes or variations other than the invention and Examples that can be understood from the overall specification within the scope of the technical concept of the present invention.

### Example 1

20 kg of a raw material made from copper (Cu: purity 4N), and Ga (purity: 4N) that was adjusted so that the Ga concentration becomes a composition ratio of 22 at %, was placed in a carbon crucible, and the inside of the crucible was made to be a nitrogen gas atmosphere and heated to 1250° C. This high temperature heating was performed to weld a dummy bar and Cu—Ga alloy molten metal.

A resistance heating apparatus (graphite element) was used for heating the crucible. The shape of the melting crucible was 140 mmφ×400 mmφ, the mold was made from graphite, the shape of the cast ingot was a plate shape of 65 mmw×12 mmt, and this was subject to continuous casting.

After melting the raw material, the molten metal temperature was lowered to 990° C. (temperature that is approximately 100° C. higher than the melting point), and, at the time that the molten metal temperature and the mold temperature became stabilized, drawing was started. Since a dummy bar is inserted at the front end of the mold, the solidified cast piece can be drawn by pulling out the dummy bar.

The drawing pattern was as follows; namely, driving for 0.5 seconds and stopping for 2.5 seconds were repeated, and the frequency was changed. The drawing rate was 30 mm/min. The drawing rate (mm/min) and the cooling rate (° C./min) are of a proportional relation, and, when the drawing rate (mm/min) is increased, the cooling rate will also increase. Consequently, the cooling rate was 200° C./min.

This cast piece was machined into a target shape and additionally polished, and the polished surface was etched with a nitric acid solution that was diluted two-fold with water, and the etched surface was observed with a microscope. Consequently, the γ phase (segregated phase, heterophase) with a high Ga concentration was finely and uniformly dispersed in the ζ phase in which Ga exists as a solid solution in Cu, and the size of the γ phase was 3 μm and satisfied the relational expression of D=7×C−150. The oxygen concentration was less than 10 wtppm. Moreover, the impurity content was as follows; namely, P: 1.5 wtppm, Fe: 2.4 wtppm, Ni: 1.1 wtppm, and Ag: 7 wtppm. By sputtering this kind of Cu—Ga alloy target with a low oxygen content and impurity content and having a cast structure in which the γ phase (segregated phase) is uniformly dispersed, it was possible to obtain a homogeneous Cu—Ga-based alloy film without much generation of particles.

Moreover, as a result of observing the obtained film via X-ray diffraction, since only the peaks of the ζ phase and the γ phase were observed, it has been confirmed that this cast structure is only configured from these two phases.

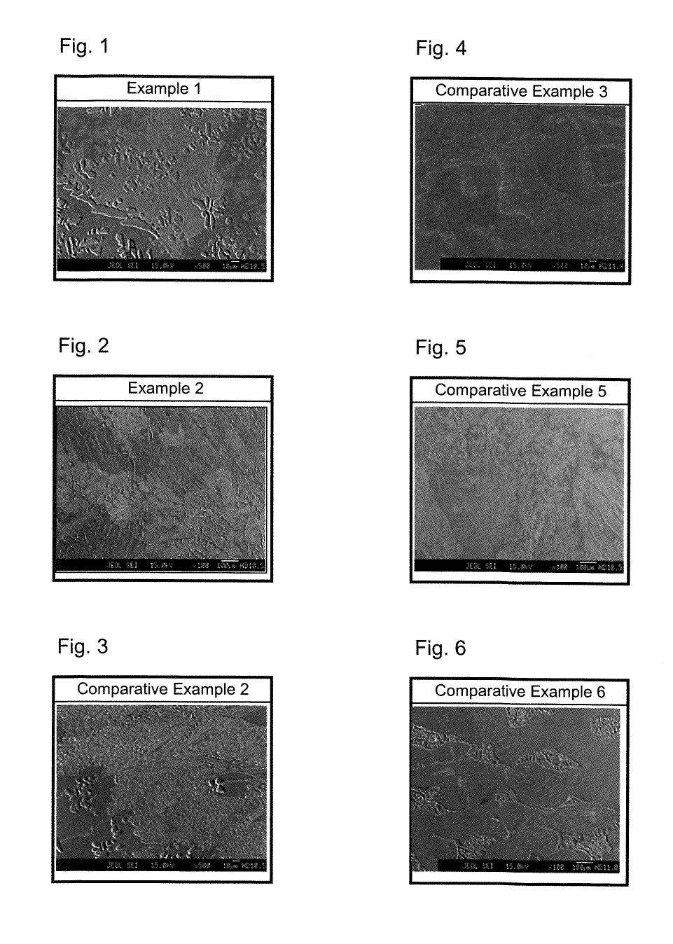

TABLE 1

| | | | Ga | Oxygen | | | | | | | |
|---|---|---|---|---|---|---|---|---|---|---|---|
| | | | Composi- | Concentra- | | | | | | Heterophase | |
| | | | tion | tion | | Impurity | | | | (γ phase | |
| | Method | Condition | (at %) | (wtppm) | Structure | P | Fe | Ni | Ag | size) | Remarks |
| Example 1 | continuous | drawing rate: 30 mm/min | 22 | <10 | — | 1.5 | 2.4 | 1.1 | 7 | 3μ | |
| | casting | (cooling rate: 200° C./min) | | | | | | | | | |
| Example 2 | continuous | drawing rate: 90 mm/min | 22 | 10 | — | 1.3 | 2.1 | 0.9 | 5.8 | 2μ | |
| | casting | (cooling rate: 600° C./min) | | | | | | | | | |
| Example 3 | continuous | drawing rate: 30 mm/min | 25 | 20 | FIG. 1 | 1.4 | 1.5 | 0.7 | 4.3 | 11μ | |
| | casting | (cooling rate: 200° C./min) | | | | | | | | | |
| Example 4 | continuous | drawing rate: 90 mm/min | 25 | 10 | — | 0.8 | 3.2 | 1.4 | 6.7 | 8μ | |
| | casting | (cooling rate: 600° C./min) | | | | | | | | | |
| Example 5 | continuous | drawing rate: 30 mm/min | 29 | 10 | FIG. 2 | 0.6 | 4.7 | 1.5 | 7.4 | 46μ | |
| | casting | (cooling rate: 200° C./min) | | | | | | | | | |
| Example 6 | continuous | drawing rate: 90 mm/min | 29 | 20 | — | 0.9 | 3.3 | 1.1 | 5.4 | 43μ | |
| | casting | (cooling rate: 600° C./min) | | | | | | | | | |
| Comparative | melting | melting: 1100° C. | 22 | <20 | — | 6 | 10 | 2.2 | 10 | 8μ | |
| Example 1 | and casting | natural cooling, inside | | | | | | | | | |
| | | crucible (10° C./min) | | | | | | | | | |
| Comparative | continuous | drawing rate: 20 mm/min | 25 | 20 | FIG. 3 | 1.4 | 2.2 | 1 | 5.9 | 12μ | lamellar |
| Example 2 | casting | (cooling rate: 130° C./min) | | | | | | | | | structure |
| | | | | | | | | | | | (layered |
| | | | | | | | | | | | structure) |
| Comparative | melting | melting: 1100° C. | 25 | 40 | FIG. 4 | 4 | 8.2 | 1.3 | 9 | 43μ | large |
| Example 3 | and casting | natural cooling, inside | | | | | | | | | heterophase |
| | | crucible (10° C./min) | | | | | | | | | |
| Comparative | powder | water atomizated powder, | 25 | 320 | — | 15 | 30 | 3.8 | 13 | 10μ | high oxygen |
| Example 4 | sintering | temperature: 600° C., | | | | | | | | | content |
| | | surface pressure: | | | | | | | | | |
| | | 250 kgf/cm²HP | | | | | | | | | |
| Comparative | continuous | drawing rate: 20 mm/min | 29 | 20 | FIG. 5 | 0.6 | 4.5 | 1.3 | 7.2 | 67μ | non-uniform |
| Example 5 | casting | (cooling rate: 130° C./min) | | | | | | | | | γ phase |
| Comparative | melting | melting: 1100° C. | 29 | 70 | FIG. 6 | 7 | 9.5 | 2.1 | 8 | >100μ | highly coarse |
| Example 6 | and casting | natural cooling, inside | | | | | | | | | γ phase |
| | | crucible (10° C./min) | | | | | | | | | |

### Example 2

20 kg of a raw material made from copper (Cu: purity 4N), and Ga (purity: 4N) that was adjusted so that the Ga concentration becomes a composition ratio of 22 at %, was placed in a carbon crucible, and the inside of the crucible was made to be a nitrogen gas atmosphere and heated to 1250° C. This high temperature heating was performed to weld a dummy bar and Cu—Ga alloy molten metal.

A resistance heating apparatus (graphite element) was used for heating the crucible. The shape of the melting crucible was 140 mmφ×400 mmφ, the mold was made from graphite, the shape of the cast ingot was a plate shape of 65 mmw×12 mmt, and this was subject to continuous casting.

After melting the raw material, the molten metal temperature was lowered to 990° C. (temperature that is approximately 100° C. higher than the melting point), and, at the time that the molten metal temperature and the mold temperature became stabilized, drawing was started. Since a dummy bar is inserted at the front end of the mold, the solidified cast piece can be drawn by pulling out the dummy bar.

The drawing pattern was as follows; namely, driving for 0.5 seconds and stopping for 2.5 seconds were repeated, and the frequency was changed. The drawing rate was 90 mm/min. The drawing rate (mm/min) and the cooling rate (° C./min) are of a proportional relation, and, when the drawing rate (mm/min) is increased, the cooling rate will also increase. Consequently, the cooling rate was 600° C./min.

This cast piece was machined into a target shape and additionally polished, and the polished surface was etched with a nitric acid solution that was diluted two-fold with water, and the etched surface was observed with a microscope. Consequently, the γ phase (segregated phase, heterophase) with a high Ga concentration was finely and uniformly dispersed in the ζ phase in which Ga exists as a solid solution in Cu, and the size of the γ phase was 2 μm and satisfied the relational expression of D=7×C−150. The oxygen concentration was less than 10 wtppm. Moreover, the impurity content was as follows; namely, P: 1.3 wtppm, Fe: 2.1 wtppm, Ni: 0.9 wtppm, and Ag: 5.8 wtppm.

By sputtering this kind of Cu—Ga alloy target with a low oxygen content and impurity content and having a cast structure in which the γ phase (segregated phase) is uniformly dispersed, it was possible to obtain a homogeneous Cu—Ga-based alloy film without much generation of particles.

Moreover, as a result of observing the obtained film via X-ray diffraction, since only the peaks of the ζ phase and the γ phase were observed, it has been confirmed that this cast structure is only configured from these two phases.

### Example 3

20 kg of a raw material made from copper (Cu: purity 4N), and Ga (purity: 4N) that was adjusted so that the Ga concentration becomes a composition ratio of 25 at %, was placed in a carbon crucible, and the inside of the crucible was made to be a nitrogen gas atmosphere and heated to 1250° C. This high temperature heating was performed to weld a dummy bar and Cu—Ga alloy molten metal.

A resistance heating apparatus (graphite element) was used for heating the crucible. The shape of the melting crucible was 140 mmφ×400 mmφ, the mold was made from graphite, the shape of the cast ingot was a plate shape of 65 mmw×12 mmt, and this was subject to continuous casting.

After melting the raw material, the molten metal temperature was lowered to 990° C. (temperature that is approximately 100° C. higher than the melting point), and, at the time that the molten metal temperature and the mold temperature became stabilized, drawing was started. Since a dummy bar is inserted at the front end of the mold, the solidified cast piece can be drawn by pulling out the dummy bar.

The drawing pattern was as follows; namely, driving for 0.5 seconds and stopping for 2.5 seconds were repeated, and the frequency was changed. The drawing rate was 30 mm/min. The drawing rate (mm/min) and the cooling rate (° C./min) are of a proportional relation, and, when the drawing rate (mm/min) is increased, the cooling rate will also increase. Consequently, the cooling rate was 200° C./min.

This cast piece was machined into a target shape and additionally polished, and the polished surface was etched with a nitric acid solution that was diluted two-fold with water, and the microphotograph of the etched surface is shown in FIG. 1. Consequently, the γ phase (segregated phase, heterophase) with a high Ga concentration was finely and uniformly dispersed in the ζ phase in which Ga exists as a solid solution in Cu, and the size of the γ phase was 11 μm and satisfied the relational expression of D=7×C−150. The oxygen concentration was less than 20 wtppm. Moreover, the impurity content was as follows; namely, P: 1.4 wtppm, Fe: 1.5 wtppm, Ni: 0.7 wtppm, and Ag: 4.3 wtppm.

By sputtering this kind of Cu—Ga alloy target with a low oxygen content and impurity content and having a cast structure in which the γ phase (segregated phase) is uniformly dispersed, it was possible to obtain a homogeneous Cu—Ga-based alloy film without much generation of particles.

Moreover, as a result of observing the obtained film via X-ray diffraction, since only the peaks of the ζ phase and the γ phase were observed as shown in FIG. 11, it has been confirmed that this cast structure is only configured from these two phases.

### Example 4

20 kg of a raw material made from copper (Cu: purity 4N), and Ga (purity: 4N) that was adjusted so that the Ga concentration becomes a composition ratio of 25 at %, was placed in a carbon crucible, and the inside of the crucible was made to be a nitrogen gas atmosphere and heated to 1250° C. This high temperature heating was performed to weld a dummy bar and Cu—Ga alloy molten metal.

A resistance heating apparatus (graphite element) was used for heating the crucible. The shape of the melting crucible was 140 mmφ×400 mmφ, the mold was made from graphite, the shape of the cast ingot was a plate shape of 65 mmw×12 mmt, and this was subject to continuous casting.

After melting the raw material, the molten metal temperature was lowered to 990° C. (temperature that is approximately 100° C. higher than the melting point), and, at the time that the molten metal temperature and the mold temperature became stabilized, drawing was started. Since a dummy bar is inserted at the front end of the mold, the solidified cast piece can be drawn by pulling out the dummy bar.

The drawing pattern was as follows; namely, driving for 0.5 seconds and stopping for 2.5 seconds were repeated, and the frequency was changed. The drawing rate was 90 mm/min. The drawing rate (mm/min) and the cooling rate (° C./min) are of a proportional relation, and, when the drawing rate (mm/min) is increased, the cooling rate will also increase. Consequently, the cooling rate was 600° C./min.

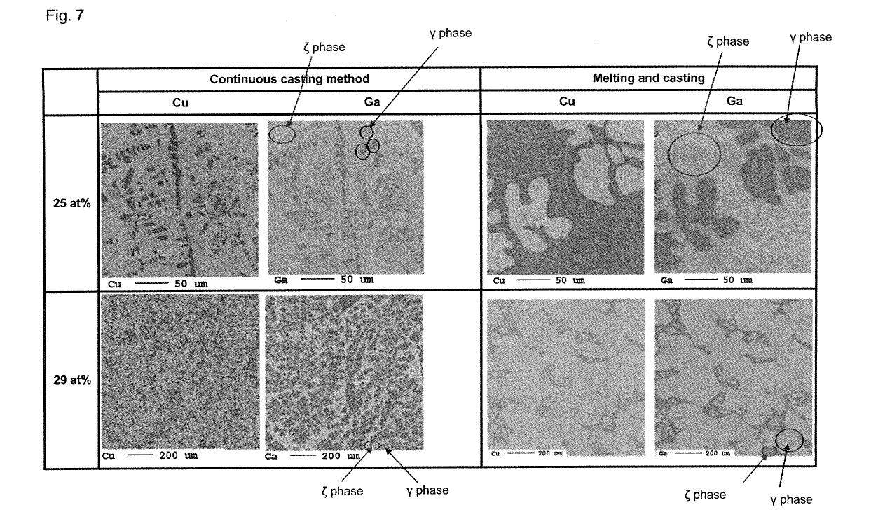

This cast piece was machined into a target shape and additionally polished, and the polished surface was etched with a nitric acid solution that was diluted two-fold with water, and the etched surface was observed. The FE-EPMA surface analysis is shown in FIG. 7 (upper left diagram). Consequently, the γ phase (segregated phase, heterophase) with a high Ga concentration was finely and uniformly dispersed in the ζ phase in which Ga exists as a solid solution in Cu, and the size of the γ phase was 8 μm and satisfied the relational expression of D=7×C−150. The oxygen concentration was less than 10 wtppm. Moreover, the impurity content was as follows; namely, P: 0.8 wtppm, Fe: 3.2 wtppm, Ni: 1.4 wtppm, and Ag: 6.7 wtppm.

By sputtering this kind of Cu—Ga alloy target with a low oxygen content and impurity content and having a cast structure in which the γ phase (segregated phase) is uniformly dispersed, it was possible to obtain a homogeneous Cu—Ga-based alloy film without much generation of particles.

### Example 5

20 kg of a raw material made from copper (Cu: purity 4N), and Ga (purity: 4N) that was adjusted so that the Ga concentration becomes a composition ratio of 29 at %, was placed in a carbon crucible, and the inside of the crucible was made to be a nitrogen gas atmosphere and heated to 1250° C. This high temperature heating was performed to weld a dummy bar and Cu—Ga alloy molten metal.

A resistance heating apparatus (graphite element) was used for heating the crucible. The shape of the melting crucible was 140 mmφ×400 mmφ, the mold was made from graphite, the shape of the cast ingot was a plate shape of 65 mmw×12 mmt, and this was subject to continuous casting.

After melting the raw material, the molten metal temperature was lowered to 970° C. (temperature that is approximately 100° C. higher than the melting point), and, at the time that the molten metal temperature and the mold temperature became stabilized, drawing was started. Since a dummy bar is inserted at the front end of the mold, the solidified cast piece can be drawn by pulling out the dummy bar.

The drawing pattern was as follows; namely, driving for 0.5 seconds and stopping for 2.5 seconds were repeated, and the frequency was changed. The drawing rate was 30 mm/min. The drawing rate (mm/min) and the cooling rate (° C./min) are of a proportional relation, and, when the drawing rate (mm/min) is increased, the cooling rate will also increase. Consequently, the cooling rate was 200° C./min.

This cast piece was machined into a target shape and additionally polished, and the polished surface was etched with a nitric acid solution that was diluted two-fold with water, and the microphotograph of the etched surface is shown in FIG. 2. Consequently, the γ phase (segregated phase, heterophase) with a high Ga concentration was finely and uniformly dispersed in the ζ phase in which Ga exists as a solid solution in Cu, and the size of the γ phase was 46 μm and satisfied the relational expression of D=7×C−150. The oxygen concentration was less than 10 wtppm. Moreover, the impurity content was as follows; namely, P: 0.6 wtppm, Fe: 4.7 wtppm, Ni: 1.5 wtppm, and Ag: 7.4 wtppm.

By sputtering this kind of Cu—Ga alloy target with a low oxygen content and impurity content and having a cast structure in which the γ phase (segregated phase) is uniformly dispersed, it was possible to obtain a homogeneous Cu—Ga-based alloy film without much generation of particles.

### Example 6

20 kg of a raw material made from copper (Cu: purity 4N), and Ga (purity: 4N) that was adjusted so that the Ga concentration becomes a composition ratio of 29 at %, was placed in a carbon crucible, and the inside of the crucible was made to be a nitrogen gas atmosphere and heated to 1250° C. This high temperature heating was performed to weld a dummy bar and Cu—Ga alloy molten metal.

A resistance heating apparatus (graphite element) was used for heating the crucible. The shape of the melting crucible was 140 mmφ×400 mmφ, the mold was made from graphite, the shape of the cast ingot was a plate shape of 65 mmw×12 mmt, and this was subject to continuous casting.

After melting the raw material, the molten metal temperature was lowered to 970° C. (temperature that is approximately 100° C. higher than the melting point), and, at the time that the molten metal temperature and the mold temperature became stabilized, drawing was started. Since a dummy bar is inserted at the front end of the mold, the solidified cast piece can be drawn by pulling out the dummy bar.

The drawing pattern was as follows; namely, driving for 0.5 seconds and stopping for 2.5 seconds were repeated, and the frequency was changed. The drawing rate was 90 mm/min. The drawing rate (mm/min) and the cooling rate (° C./min) are of a proportional relation, and, when the drawing rate (mm/min) is increased, the cooling rate will also increase. Consequently, the cooling rate was 600° C./min.

This cast piece was machined into a target shape and additionally polished, and the polished surface was etched with a nitric acid solution that was diluted two-fold with water, and the etched surface was observed. The FE-EPMA surface analysis is shown in FIG. 6 (lower left diagram). Consequently, the γ phase (segregated phase, heterophase) with a high Ga concentration was finely and uniformly dispersed in the ζ phase in which Ga exists as a solid solution in Cu, and the size of the γ phase was 43 μm and satisfied the relational expression of D=7×C−150. The oxygen concentration was less than 20 wtppm. Moreover, the impurity content was as follows; namely, P: 0.9 wtppm, Fe: 3.3 wtppm, Ni: 1.1 wtppm, and Ag: 5.4 wtppm.

By sputtering this kind of Cu—Ga alloy target with a low oxygen content and impurity content and having a cast structure in which the γ phase (segregated phase) is uniformly dispersed, it was possible to obtain a homogeneous Cu—Ga-based alloy film without much generation of particles.

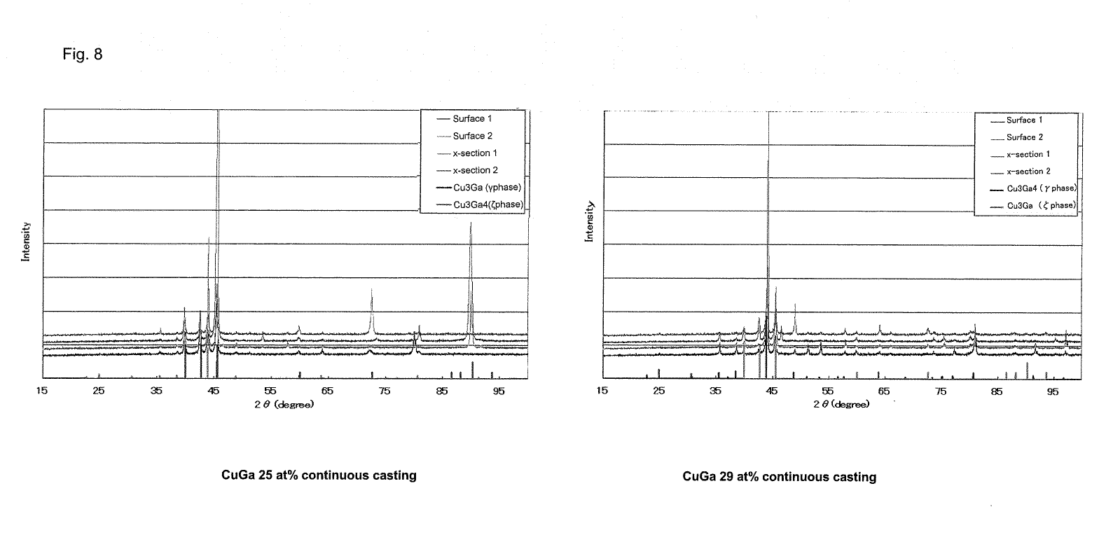

Moreover, as a result of observing the obtained film via X-ray diffraction, since only the peaks of the ζ phase and the γ phase were observed as shown in FIG. 8, it has been confirmed that this cast structure is only configured from these two phases.

### Comparative Example 1

5 kg of a raw material made from copper (Cu: purity 4N), and Ga (purity: 4N) that was adjusted so that the Ga concentration becomes a composition ratio of 25 at %, was placed in a carbon crucible having a diameter of φ200 mm, the inside of the crucible was made to be an Ar gas atmosphere, and the raw material was heated and melted at 1100° C. for 2 hours. Here, the rate of temperature increase was set to 10° C./min. Subsequently, the cooling rate from 1100° C. to 200° C. was set to approximately 10° C./min, and the inside of the crucible was naturally cooled to solidify the molten metal.

The obtained cast piece was machined into a target shape and additionally polished, and the polished surface was etched with a nitric acid solution that was diluted two-fold with water, and the etched surface was observed. Consequently, the size of the γ phase that precipitated in the ζ phase was 8 μm and failed to satisfy the relational expression of D=7×C−150. The oxygen concentration exceeded 20 wtppm, and the impurity content was as follows; namely, P: 6 wtppm, Fe: 10 wtppm, Ni: 2.2 wtppm, and Ag: 10 wtppm.

By sputtering this kind of Cu—Ga alloy target having a cast structure containing a large γ phase (segregated phase), the generation of particles increased, and it was not possible to obtain a homogeneous Cu—Ga-based alloy film.

### Comparative Example 2

20 kg of a raw material made from copper (Cu: purity 4N), and Ga (purity: 4N) that was adjusted so that the Ga concentration becomes a composition ratio of 25 at %, was placed in a carbon crucible, and the inside of the crucible was made to be a nitrogen gas atmosphere and heated to 1250° C. This high temperature heating was performed to weld a dummy bar and Cu—Ga alloy molten metal.

A resistance heating apparatus (graphite element) was used for heating the crucible. The shape of the melting crucible was 140 mmφ×400 mmφ, the mold was made from graphite, the shape of the cast ingot was a plate shape of 65 mmw×12 mmt, and this was subject to continuous casting.

After melting the raw material, the molten metal temperature was lowered to 990° C. (temperature that is approximately 100° C. higher than the melting point), and, at the time that the molten metal temperature and the mold temperature became stabilized, drawing was started. Since a dummy bar is inserted at the front end of the mold, the solidified cast piece can be drawn by pulling out the dummy bar.

The drawing pattern was as follows; namely, driving for 0.5 seconds and stopping for 2.5 seconds were repeated, and the frequency was changed. The drawing rate was 20 mm/min. The drawing rate (mm/min) and the cooling rate (° C./min) are of a proportional relation, and, when the drawing rate (mm/min) is increased, the cooling rate will also increase. Consequently, the cooling rate was 130° C./min.

This cast piece was machined into a target shape and additionally polished, and the polished surface was etched with a nitric acid solution that was diluted two-fold with water, and the microphotograph of the etched surface is shown in FIG. 5. Consequently, as shown in FIG. 5, a lamellar structure (layered structure) in which two phases (γ phase and ζ phase) alternatively exist in a thin plate shape or an oval shape in intervals of several microns appeared, and the γ phase was not dispersed uniformly and finely. The oxygen concentration was 20 wtppm, and the impurity content was as follows; namely, P: 1.4 wtppm, Fe: 2.2 wtppm, Ni: 1 wtppm, and Ag: 5.9 wtppm.

By sputtering this kind of Cu—Ga alloy target having a cast structure partially containing a lamellar structure, the generation of particles increased, and it was not possible to obtain a favorable Cu—Ga-based alloy film.

### Comparative Example 3

5 kg of a raw material made from copper (Cu: purity 4N), and Ga (purity: 4N) that was adjusted so that the Ga concentration becomes a composition ratio of 25 at %, was placed in a carbon crucible having a diameter of φ200 mm, the inside of the crucible was made to be an Ar gas atmosphere, and the raw material was heated and melted at 1100° C. for 2 hours. Here, the rate of temperature increase was set to 10° C./min. Subsequently, the cooling rate from 1100° C. to 200° C. was set to approximately 10° C./min, and the inside of the crucible was naturally cooled to solidify the molten metal.

The obtained cast piece was machined into a target shape and additionally polished, and the polished surface was etched with a nitric acid solution that was diluted two-fold with water. The micrograph of the etched surface is shown in FIG. 6 and the FE-EPMA surface analysis is shown in FIG. 10 (upper right diagram). Consequently, the size of the γ phase that precipitated in the ζ phase was 43 μm and failed to satisfy the relational expression of D=7×C−150. Moreover, the oxygen concentration increased to 40 wtppm, and the impurity content was as follows; namely, P: 4 wtppm, Fe: 8.2 wtppm, Ni: 1.3 wtppm, and Ag: 9 wtppm.

By sputtering this kind of Cu—Ga alloy target having a cast structure containing a large γ phase (segregated phase), the generation of particles increased, and it was not possible to obtain a homogeneous Cu—Ga-based alloy film.

### Comparative Example 4

20 kg of a raw material made from copper (Cu: purity 4N), and Ga (purity: 4N) that was adjusted so that the Ga concentration becomes a composition ratio of 29 at % was placed in a carbon crucible, the inside of the crucible was made to be a nitrogen gas atmosphere, and the raw material was heated to 1250° C. and melted.

This molten article was subject to water atomization to prepare a Cu—Ga alloy powder having a grain size that is less than 90 μm. The thus prepared Cu—Ga alloy powder was subject to hot press sintering at 600° C. for 2 hours at a surface pressure of 250 kgf/cm².

This sintered piece was machined into a target shape and additionally polished, and the polished surface was etched with a nitric acid solution that was diluted two-fold with water, and the microphotograph of the etched surface is shown in FIG. 7. Consequently, while the size of the γ phase was fine at 10 μm, the oxygen content increased to 320 wtppm. Moreover, the impurity content was as follows; namely, P: 15 wtppm, Fe: 30 wtppm, Ni: 3.8 wtppm, and Ag: 13 wtppm.

By sputtering this kind of Cu—Ga alloy target having a high oxygen content and impurity content, the generation of particles increased, and it was not possible to obtain a favorable Cu—Ga-based alloy film.

### Comparative Example 5

20 kg of a raw material made from copper (Cu: purity 4N), and Ga (purity: 4N) that was adjusted so that the Ga concentration becomes a composition ratio of 29 at %, was placed in a carbon crucible and the inside of the crucible was made to be a nitrogen gas atmosphere and heated to 1250° C. This high temperature heating was performed to weld a dummy bar and Cu—Ga alloy molten metal.

A resistance heating apparatus (graphite element) was used for heating the crucible. The shape of the melting crucible was 140 mm ×400 mmφ, the mold was made from graphite, the shape of the cast ingot was a plate shape of 65 mmw×12 mmt, and this was subject to continuous casting.

After melting the raw material, the molten metal temperature was lowered to 970° C. (temperature that is approximately 100° C. higher than the melting point), and, at the time that the molten metal temperature and the mold temperature became stabilized, drawing was started. Since a dummy bar is inserted at the front end of the mold, the solidified cast piece can be drawn by pulling out the dummy bar.

The drawing pattern was as follows; namely, driving for 0.5 seconds and stopping for 2.5 seconds were repeated, and the frequency was changed. The drawing rate was 20 mm/min. The drawing rate (mm/min) and the cooling rate (° C./min) are of a proportional relation, and, when the drawing rate (mm/min) is increased, the cooling rate will also increase. Consequently, the cooling rate was 130° C./min.

This cast piece was machined into a target shape and additionally polished, and the polished surface was etched with a nitric acid solution that was diluted two-fold with water, and the microphotograph of the etched surface is shown in FIG. 8. Consequently, the size of the γ phase that precipitated in the ζ phase was 67 μm and failed to satisfy the relational expression of D=7×C−150, and the size of the γ phase was non-uniform. The oxygen concentration was 20 wtppm, and the impurity content was as follows; namely, P: 0.6 wtppm, Fe: 4.5 wtppm, Ni: 1.3 wtppm, and Ag:

7.2 wtppm.

By sputtering this kind of Cu—Ga alloy target having a cast structure containing a non-uniform γ phase, the generation of particles increased, and it was not possible to obtain a favorable Cu—Ga-based alloy film.

### Comparative Example 6

5 kg of a raw material made from copper (Cu: purity 4N), and Ga (purity: 4N) that was adjusted so that the Ga concentration becomes a composition ratio of 29 at %, was placed in a carbon crucible having a diameter of φ200 mm, the inside of the crucible was made to be an Ar gas atmosphere, and the raw material was heated and melted at 1100° C. for 2 hours. Here, the rate of temperature increase was set to 10° C./min. Subsequently, the cooling rate from 1100° C. to 200° C. was set to approximately 10° C./min, and the inside of the crucible was naturally cooled to solidify the molten metal.

The obtained cast piece was machined into a target shape and additionally polished, and the polished surface was etched with a nitric acid solution that was diluted two-fold with water. The micrograph of the etched surface is shown in FIG. 9 and the FE-EPMA surface analysis is shown in FIG. 10 (lower right diagram). Consequently, the: size of the γ phase that precipitated in the ζ phase exceeded 100 μm and failed to satisfy the relational expression of D=7×C−150. Moreover, the oxygen concentration increased to 70 wtppm, and the impurity content was as follows; namely, P: 7 wtppm, Fe: 9.5 wtppm, Ni: 2.1 wtppm, and Ag: 8 wtppm.

By sputtering this kind of Cu—Ga alloy target having a cast structure containing an extremely coarse γ phase (segregated phase), the generation of particles increased, and it was not possible to obtain a homogeneous Cu—Ga-based alloy film.

According to the present invention, there is a considerable advantage in that gas components such as oxygen can be reduced in comparison to a sintered compact target, and, by continuously solidifying the sputtering target having the foregoing cast structure under a solidifying condition of a constant cooling rate, the present invention yields the effect of being able to reduce oxygen and obtain a target with a favorable cast structure, in which the γ phase is finely and uniformly dispersed in the ζ phase of an intermetallic compound as the parent phase.

As a result of sputtering a Cu—Ga alloy target with a low oxygen content and having a cast structure in which the segregation is dispersed, the present invention yields the effect of being able to obtain a homogeneous Cu—Ga-based alloy film with low generation of particles, and additionally yields the effect of being able to considerably reduce the production cost of the Cu—Ga alloy target.

Since the light-absorbing layer and CIGS-based solar cells can be produced from the foregoing sputtered film, the present invention is effective for inhibiting the deterioration in the conversion efficiency of the CIGS solar cells.

1. A melted and cast Cu—Ga alloy sputtering target containing 22 at % or more and 29 at % or less of Ga, and remainder being Cu and unavoidable impurities, wherein the Cu—Ga alloy sputtering target has an eutectoid structure,. excluding a structure containing a lamellar structure, configured from a mixed phase of a ζ phase, which is an intermetallic compound layer of Cu and Ga, and a γ phase, and satisfies a relational expression of D≦7×C−150 when a diameter of the γ phase is D μm and a Ga concentration is C at %.

2. The Cu—Ga alloy sputtering target according to claim 1, wherein an oxygen content is 100 wtppm or less.

3. The Cu—Ga alloy sputtering target according to claim 2, wherein a content of each of Fe, Ni, Ag and P as impurities is 10 wtppm or less.

4. A method of producing a Cu—Ga alloy sputtering target including the steps of melting a target raw material in a graphite crucible, pouring resulting molten metal in a mold comprising a water-cooled probe to continuously produce a casting formed from a Cu—Ga alloy, and additionally machining the obtained casting to produce the Cu—Ga alloy target, wherein a solidification rate of the casting reaching 300° C. from a melting point is controlled to 200 to 1000° C./min

5. The method of producing a Cu—Ga alloy sputtering target according to claim 4, wherein a drawing rate is set to 30 mm/min to 150 mm/min.

6. The method of producing a Cu—Ga alloy sputtering target according to claim 5, wherein a horizontal or a vertical continuous casting method is used.

7. The method of producing a Cu—Ga alloy sputtering target according to claim 6, wherein an amount and a concentration of a γ phase and a ζ phase formed during casting is adjusted by controlling the solidification rate of the casting reaching 300° C. from the melting point is controlled to 200 to 1000° C./min.

8. The method of producing a Cu—Ga alloy sputtering target according to claim 4, wherein a horizontal or a vertical continuous casting method is used.

9. The method of producing a Cu—Ga alloy sputtering target according to claim 4, wherein an amount and a concentration of a γ phase and a ζ phase formed during casting is adjusted by controlling the solidification rate of the casting reaching 300° C. from the melting point is controlled to 200 to 1000° C./min.

10. The Cu—Ga alloy sputtering target according to claim 1, wherein a content of each of Fe, Ni, Ag and P as impurities is 10 wtppm or less.
